(19) United States
(12) Patent Application Publication
(10) Pub. No.: US 2013/0153023 A1
(43) Pub. Date: Jun. 20, 2013

(54) SOLAR CELL AND METHOD OF MANUFACTURING THE SAME

(71) Applicant: Sanyo Electric Co., Ltd., Osaka (JP)

(72) Inventors: Hiroyuki Mori, Osaka (JP); Takahiro Mishima, Osaka (JP)

(73) Assignee: SANYO ELECTRIC CO., LTD., Osaka (JP)

(21) Appl. No.: 13/769,940

(22) Filed: Feb. 19, 2013

Related U.S. Application Data
(63) Continuation of application No. PCT/JP2011/068909, filed on Aug. 23, 2011.

(30) Foreign Application Priority Data
Aug. 24, 2010 (JP) 2010-187266

(51) Int. Cl. H01L 31/0224; H01L 31/18

(52) U.S. Cl. CPC H01L 31/022441; H01L 31/18
USPC 136/256; 438/98

(57) ABSTRACT

A solar cell includes a solar cell substrate. The solar cell substrate includes a semiconductor substrate, a surface of a p-type region and a surface of an n-type region exposed on a first principal surface of the solar cell substrate. The solar cell substrate includes a p-side electrode formed on the surface of the p-type region, and an n-side electrode formed on the surface of the n-type region. The semiconductor substrate includes linear grooves extending in a first direction on a surface on a first principal surface side. Each of the p-side electrode and the n-side electrode includes a linear portion extending in the first direction.

### CROSS REFERENCE TO RELATED APPLICATIONS

This application is a continuation application of International Application No. PCT/JP2011/068909, filed on Aug. 23, 2011, entitled “METHOD OF MANUFACTURING SOLAR CELL MODULE”, which claims priority based on Article 8 of Patent Cooperation Treaty from prior Japanese Patent Applications No. 2010-187266, filed on Aug. 24, 2010, the entire contents of which are incorporated herein by reference.

### BACKGROUND OF THE INVENTION

1. Field of the Invention

This disclosure relates to a back contact solar cell and a method of manufacturing the same.

2. Description of the Related Art

Recently, solar cells are drawing much attention as an energy source placing only a small load on the environment. For this reason, more and more research and development is being undertaken on solar cells. In particular, an important issue is how to improve conversion efficiency of solar cells. Hence, research and development is heating up especially for solar cells having improved conversion efficiency and methods of manufacturing such solar cells.

As a solar cell with high conversion efficiency, Japanese Patent Application Publication No. 2009-200267 and the like, for example, propose a so-called back contact solar cell with a p-type region and an n-type region formed on a back surface side of the solar cell. In this back contact solar cell, electrodes for collecting carriers do not necessarily need to be provided on a light-receiving surface. Accordingly, light-reception efficiency can be improved in a back contact solar cell, whereby improved conversion efficiency can be achieved.

### SUMMARY OF THE INVENTION

However, there is a demand for further improvement in conversion efficiency of solar cells.

An aspect of the invention is made in view of this point, and aims to improve conversion efficiency of a back contact solar cell.

A first aspect of the invention is a solar cell. The solar cell includes a solar cell substrate, a p-side electrode, and an n-side electrode. The solar cell substrate includes a semiconductor substrate. A surface of a p-type region and a surface of an n-type region are exposed on a first principal surface of the solar cell substrate. The p-side electrode is formed on the surface of the p-side region, and the n-side electrode is formed on the surface of the n-side region. The semiconductor substrate includes, on a surface on the first principal surface side, linear grooves extending in a first direction. Each of the p-side electrode and the n-side electrode includes a linear portion extending in the first direction.

A second aspect of the invention is a method of manufacturing a solar cell. The method includes: preparing a semiconductor substrate having a principal surface on which linear grooves extending in a first direction are formed; forming, by use of the semiconductor substrate, a solar cell substrate on which a surface of a p-type region and a surface of an n-type region are exposed on a principal surface side; and forming a p-side electrode on the surface of the p-type region and forming an n-side electrode on the surface of the n-type region such that each of the p-side electrode and the n-side electrode includes a linear portion extending in the first direction.

According to the aspects of the invention, conversion efficiency of a back contact solar cell can be improved.

### BRIEF DESCRIPTION OF THE DRAWINGS

FIG. 1 is a simplified plan view of a solar cell of a first embodiment.

FIG. 2 is a schematic plan view of a semiconductor substrate.

FIG. 3 is a simplified cross-section taken along a line III-III of FIG. 2

FIG. 4 is a simplified cross-section taken along a line IV-IV of FIG. 1.

FIG. 5 is a schematic perspective view for explaining a step of manufacturing the semiconductor substrate.

FIG. 6 is a simplified cross-section for explaining a step of forming a p-type semiconductor layer in the first embodiment.

FIG. 7 is a simplified cross-section for explaining a step of forming a p-type semiconductor layer in a modified example.

FIG. 8 is a simplified cross-section of a solar cell of a second embodiment.

FIG. 9 is a schematic cross-section for explaining a step of manufacturing a solar cell substrate in the second embodiment.

### DETAILED DESCRIPTION OF EMBODIMENTS

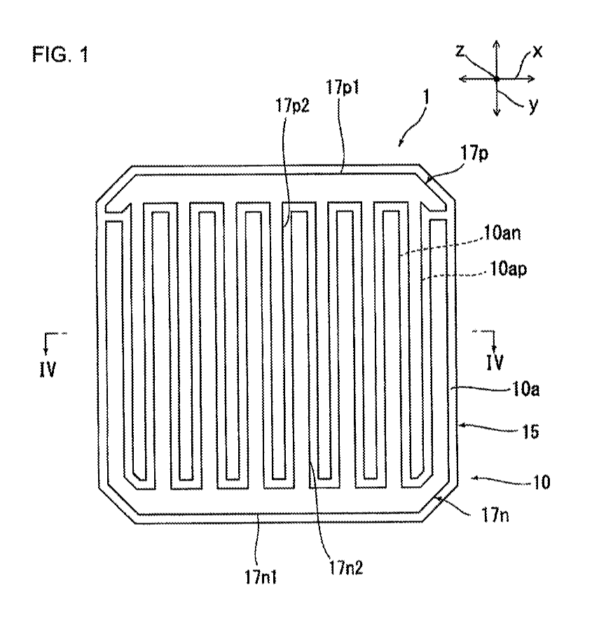

Hereinafter, preferred embodiments of the invention are described by using solar cell 1 shown in FIG. 1 as an example. Note, however, that solar cell 1 is only an example. The invention is not limited to solar cell 1 in any way.

In the drawings referenced in the embodiments and the like, members having substantially the same functions are assigned the same reference numerals. The drawings referenced in the embodiments and the like are schematic. The ratio and the like of dimensions of objects depicted in the drawings may differ from actual dimensional ratios of the objects. Concrete dimensional ratios and the like of the objects should be determined in consideration of the following description.

Although solar cell 1 can be used alone, in a case where sufficient output cannot be obtained by a single solar cell 1, solar cell 1 may be used as a solar cell module in which multiple solar cells 1 are connected by using one or more wiring materials.

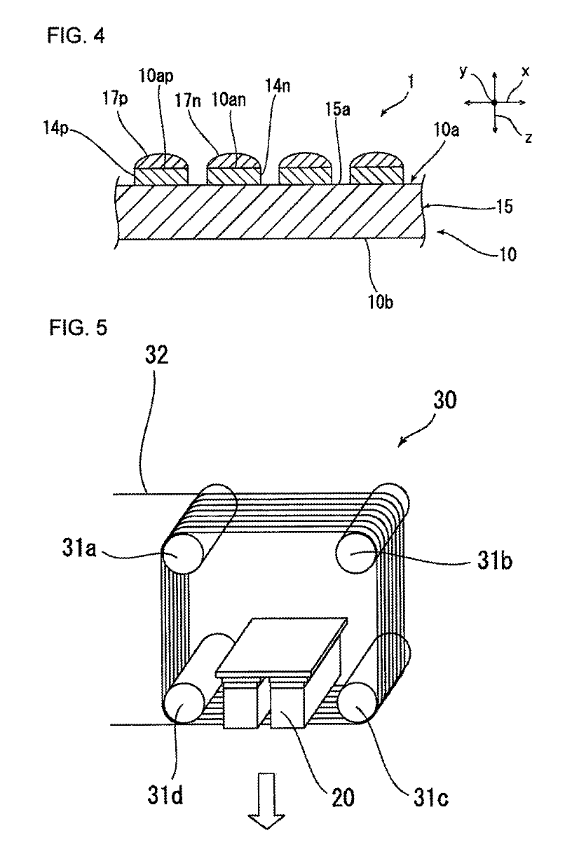

As shown in FIGS. 1 and 4, solar cell 1 includes solar cell substrate 10 or a solar cell body. Solar cell substrate 10 has back surface 10a as a first principal surface, and light-receiving surface 10b as a second principal surface. A surface of p-type region 10ap and a surface of n-type region 10an are exposed on back surface (10a) side.

More specifically, in the first embodiment, solar cell substrate 10 includes semiconductor substrate 15, n-type semiconductor layer 14n, and p-type semiconductor layer 14p.

Semiconductor substrate 15 generates carriers by receiving light on its principal surface on a light-receiving surface side. Here, carriers refer to holes and electrons generated when light is absorbed by semiconductor substrate 15. Semiconductor substrate 15 is formed of a crystalline semiconductor substrate of n-type or p-type conductivity. Specific examples of the crystalline semiconductor substrate include crystalline silicon substrates such as a single-crystal silicon substrate and a polycrystalline silicon substrate, for example.

N-type semiconductor layer 14n and p-type semiconductor layer 14p are formed on the principal surface on a back surface side of semiconductor substrate 15. N-type semiconductor layer 14n forms n-type region 10an, and p-type semiconductor layer 14p forms p-type region 10ap.

As shown in FIG. 1, each of n-type semiconductor layer 14n and p-type semiconductor layer 14p is formed in a comb-teeth shape. N-type semiconductor layer 14n and p-type semiconductor layer 14p are formed to interdigitate each other, and are provided alternately in an x direction. Thus, p-type region 10ap and n-type region 10an are formed in comb-teeth shapes which are inserted between each other. Linear portions of p-type region 10ap extending in a y direction and linear portions of n-type region 10an extending in the y direction are arranged next to each other in the x direction.

N-type semiconductor layer 14n includes an n-type amorphous semiconductor layer formed on the principal surface of semiconductor substrate 15 on the back surface side. Meanwhile, p-type semiconductor layer 14p includes a p-type amorphous semiconductor layer formed on the principle plane of semiconductor substrate 15 on the back surface side. Note that an i-type amorphous semiconductor layer may be interposed between semiconductor substrate 15 and n-type semiconductor layer 14n, as well as between semiconductor substrate 15 and p-type semiconductor layer 14p. In this case, the i-type amorphous semiconductor layer is preferably formed of an i-type hydrogenated amorphous silicon layer having a thickness of about several angstroms to 250 angstroms, which virtually does not contribute to power generation, for example.

The p-type amorphous semiconductor layer is a semiconductor layer of p-type conductivity, to which a p-type dopant is added. Specifically, in the first embodiment, the p-type amorphous semiconductor layer is made of a p-type hydrogenated amorphous silicon. Meanwhile, the n-type amorphous semiconductor layer is a semiconductor layer of n-type conductivity, to which an n-type dopant is added. Specifically, in the first embodiment, the n-type amorphous semiconductor layer is made of an n-type hydrogenated amorphous silicon. Note that although the thickness of each of the p-type and n-type amorphous semiconductor layers is not particularly limited, it may be about 20 angstroms to 500 angstroms, for example.

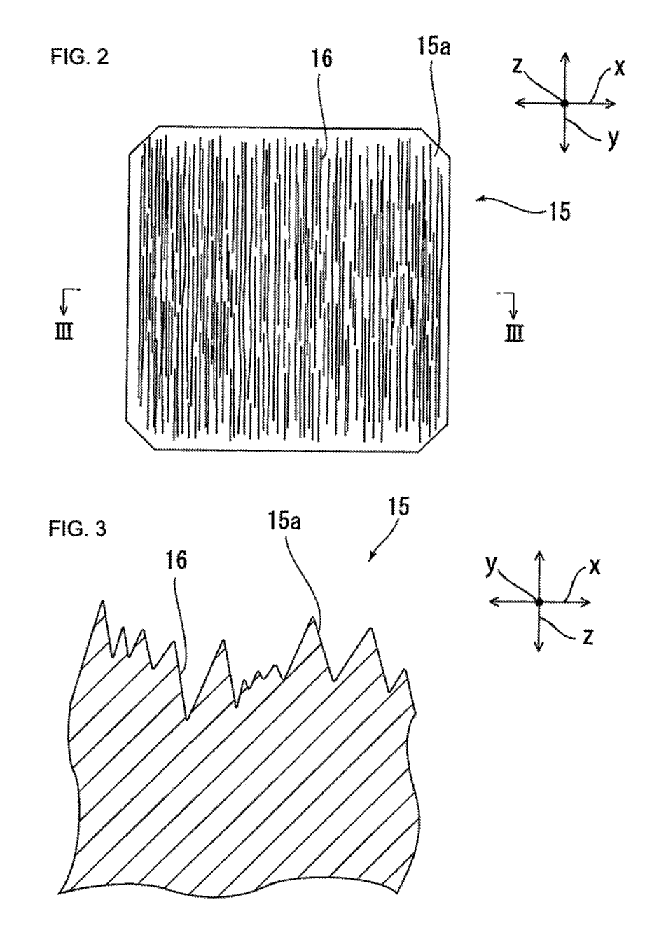

As shown in FIGS. 2 and 3, surface 15a of semiconductor substrate 15 includes linear grooves 16 extending in the y direction. In the first embodiment, linear grooves 16 are saw marks (wire traces) formed when manufacturing semiconductor substrate 15. Hence, the maximum grove width of linear grooves 16 is about 5 μm, the maximum depth thereof is about 10 μm, and the maximum length thereof is about 3 cm.

The thickness of each of p-type semiconductor layer 14p and n-type semiconductor layer 14n formed on surface 15a of semiconductor substrate 15 is smaller than the depth of linear grooves 16. For this reason, the shape of a surface of the solar cell substrate 10 on which p-type semiconductor layer 14p and n-type semiconductor layer 14n are formed corresponds to the shape of surface 15a of semiconductor substrate 15. In other words, back surface 10a of solar cell substrate 10 has linear grooves formed on almost the entire surface.

As shown in FIG. 4, p-side electrode 17p is formed on a surface of p-type region 10ap formed of p-type semiconductor layer 14p. Meanwhile, n-side electrode 17n is formed on a surface of n-type region 10an formed of n-type semiconductor layer 14n. In the first embodiment, each of p-side electrode 17p and n-side electrode 17n is formed of a resin type conductive paste layer. Here, a resin type conductive paste layer refers to a conductive layer formed of a resin type paste including conductive particles made of metal, alloy, and the like, for example. Note that each of p-side electrode 17p and n-side electrode 17n can be made not only of a conductive paste, but also of various materials usable as an electrode.

As shown in FIG. 1, each of p-side electrode 17p and n-side electrode 17n is formed in a comb-teeth shape. The p-side electrode 17p and n-side electrode 17n are formed to interdigitate each other. Each of p-side electrode 17p and n-side electrode 17n includes bus bar electrodes 17p1, 17n1 and finger electrodes 17p2, 17n2 respectively connected to bus bar electrodes 17p1, 17n1.

Bus bar electrodes 17p1, 17n1 extend in the x direction. Meanwhile, finger electrodes 17p2, 17n2 extend in the y direction in parallel with linear grooves 16. Finger electrodes 17p2, 17n2 are arranged next to each other at predetermined intervals.

Next, an example of a method of manufacturing solar cell 1 is described.

Firstly, semiconductor substrate 15 is manufactured. To be specific, semiconductor substrate 15 can be manufactured by cutting semiconductor ingot 20 shown in FIG. 5. Semiconductor ingot 20 can be cut by cutting machine 30 shown in FIG. 5. Cutting machine 30 includes four axes 31a to 31d, wire 32 wound around axes 31a to 31d in an evenly-spaced manner, and a drive unit of wire 32 (not shown). In cutting machine 30, semiconductor substrate 15 is manufactured by cutting semiconductor ingot 20 bypassing it through wire 32 with wire 32 being moved by the drive unit. For this reason, linear grooves (saw marks) 16 are formed on surface 15a of semiconductor substrate 15.

The cutting step may be carried out in a free abrasive wire sawing during which a slurry with abrasive grains diffused therein is supplied to wire 32, or in a fixed abrasive wire sawing which uses wire 32 with abrasive grains such as diamond abrasive grains bonded thereto. While linear grooves 16 are formed in any of the cases of employing the free abrasive wire sawing process and the fixed abrasive wire sawing process, deeper linear grooves 16 are more likely to be formed in the case of employing the fixed abrasive wire sawing process.

Next, solar cell substrate 10 is manufactured by forming p-type semiconductor layer 14p and n-type semiconductor layer 14n. Note that although the first embodiment describes an example in which n-type semiconductor layer 14n is formed after forming p-type semiconductor layer 14p, p-type semiconductor layer 14p may be formed after forming n-type semiconductor layer 14n instead.

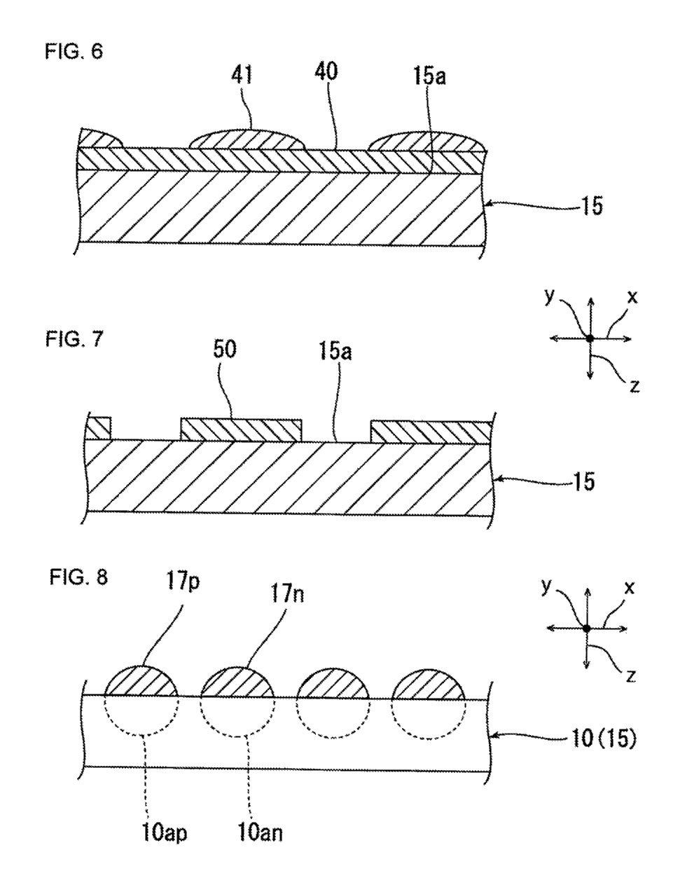

To be concrete, firstly as shown in FIG. 6, p-type amorphous silicon layer 40 is formed on surface 15a of semiconductor substrate 15. P-type amorphous silicon layer 40 can be formed by CVD (Chemical Vapor Deposition), for example. Note that since the thickness of p-type amorphous silicon layer 40 is as small as several tens of nanometers, linear irregularities corresponding to the shape of linear grooves 16 are formed on the surface of p-type amorphous silicon layer 40.

Next, etchant 41 is applied to p-type amorphous silicon layer 40 except for parts where p-type semiconductor layer 14p is to be formed. Alternatively, a resist film is formed on parts of p-type amorphous silicon layer 40 where p-type semiconductor layer 14p is to be formed, and parts other than the parts where p-type semiconductor layer 14p is to be formed are subjected to the etchant. P-type semiconductor layer 14p is formed by etching p-type amorphous silicon layer 40 in this manner. Etchant 41 is not particularly limited as long as it can be used to etch p-type amorphous silicon layer 40. As etchant 41, an etchant containing KOH, NaOH, or the like as an etching component is preferably used, for example.

Note that the term “etchant” includes an etching solution, an etching paste, an etching ink and the like. Moreover, the etchant is not only applied by use of a resist film, but also may be applied on p-type amorphous silicon layer 40 by screen printing.

Next, an n-type amorphous silicon layer for forming n-type semiconductor layer 14n is formed, and this layer is etched by an etchant to form n-type semiconductor layer 14n.

Next, p-side electrode 17p and n-side electrode 17n are respectively formed on surfaces of p-type semiconductor layer 14p and n-type semiconductor layer 14n. P-side electrode 17p and n-side electrode 17n can be formed by an electroplating method, an evaporation method, a sputtering method, or a combination of these, for example. The first embodiment describes an example in which p-side electrode 17p and n-side electrode 17n are formed by applying a resin type conductive paste containing conductive particles, and then drying the paste. As the conductive particles, preferably used are particles made of metal such as silver and copper, an alloy containing one or more of these kinds of metal, and the like, or insulating particles whose surfaces are coated with a conductive layer.

Note that in the first embodiment, finger electrodes 17p2, 17n2 of p-side electrode 17p and n-side electrode 17n are formed to extend in the y direction in parallel with the direction in which linear grooves 16 extend, and to be arranged next to each other in the x direction.

Unlike the first embodiment, it is also possible to form the finger electrodes to extend in a direction orthogonal to the direction in which the saw marks extend. However, in this case, it is difficult to form the finger electrodes, n-type semiconductor layer, and the p-type semiconductor layer with high accuracy. The reason is as follows. In this case, firstly, when applying the etchant, the etchant spreads along the saw marks and wets undesired areas in the x direction orthogonal to the direction in which the finger electrodes extend. In other words, the etchant is likely to spread in a width direction of the finger electrodes. For this reason, when patterning the p-type amorphous silicon layer, parts which should be left as the p-type semiconductor layer are partially etched as well. Hence, it is difficult to form linear portions of the p-type semiconductor layer with high accuracy. Similarly, it is also difficult to form linear portions of the n-type semiconductor layer with high accuracy. Thus, if parts of the p-type semiconductor layer and the n-type semiconductor layer that should be left are excessively etched due to lowered accuracy in forming the p-type semiconductor layer and the n-type semiconductor layer, areas thereof are reduced. Therefore, conversion efficiency of the solar cell is deteriorated.

Furthermore, if accuracy in forming the p-type semiconductor layer and the n-type semiconductor layer is lowered, it also becomes difficult to form a p-side electrode and an n-side electrode to be formed on the surface of the respective layers with high accuracy. In this case, spaces between the finger electrodes arranged next to each other need to be made large to surely insulate the p-side electrode and the n-side electrode from each other. Accordingly, minority carriers are more likely to disappear, whereby conversion efficiency is deteriorated. On the other hand, in a case where spaces between the finger electrodes arranged next to each other are reduced, a short circuit is more likely to occur between the finger electrodes arranged next to each other, whereby conversion efficiency may be deteriorated.

Meanwhile, in the first embodiment described above, finger electrodes 17p2, 17n2 of p-side electrode 17p and n-side electrode 17n are formed to extend in the y direction in parallel with the direction in which linear grooves 16 extend. Consequently, the direction in which etchant 41 spreads and the direction in which linear grooves 16 extend are parallel to each other. Thus, etchant 41 is less likely to spread and wet the linear portions (finger electrodes) in their width direction. Therefore, the linear portions of p-type semiconductor layer 14p can be formed with high accuracy. Similarly, the linear portions of n-type semiconductor layer 14n can also be formed with high accuracy. As a result, areas of the p-type semiconductor layer and the n-type semiconductor layer can be formed as designed, and a solar cell with improved conversion efficiency can be obtained.

Additionally, since the p-type semiconductor layer and the n-type semiconductor layer can be formed with high accuracy, finger electrodes 17p2, 17n2 can also be formed with high accuracy. Hence, in the first embodiment, a short-circuit is less likely to occur even if spaces between finger electrodes 17p2, 17n2 are reduced. Therefore, conversion efficiency of solar cell 1 can be improved.

Note that although the first embodiment uses saw marks to suppress the wetting and spreading of the etchant, the invention is not limited to this configuration. Dedicated linear grooves for suppressing the wetting and spreading of the etchant or the like may be formed on a semiconductor substrate instead of or in addition to the saw marks.

In addition, the first embodiment describes an example in which p-type semiconductor layer 14p and n-type semiconductor layer 14n are formed by etching the semiconductor layers. Note, however, that the invention is not limited to this. For example, as shown in FIG. 7, p-type semiconductor layer 14p (not shown in FIG. 7) may be formed on top of resist mask 50 formed by applying a resist on surface 15a of semiconductor substrate 15. N-type semiconductor layer 14n (not shown in FIG. 7) may be formed similarly by use of a resist mask. As in the case of the first embodiment described above, the wetting and spreading of the resist can be suppressed in this case as well, and thus conversion efficiency of solar cell 1 can be improved. In a case of using a conductive paste to form the p-side electrode and the n-side electrode, the wetting and spreading of the conductive paste can be suppressed as in the case of the first embodiment, whereby conversion efficiency of solar cell 1 can be improved.

Hereinafter, a description is given of another example of a preferred embodiment of the invention. Note that in the following description of the embodiment, members having functions substantially common to the first embodiment are referred to as having the common function, and descriptions thereof are omitted.

### Second Embodiment

FIG. 8 is a simplified cross-section of a solar cell of a second embodiment.

The aforementioned first embodiment describes an example in which solar cell substrate 10 is formed of semiconductor substrate 15, p-type semiconductor layer 14p, and n-type semiconductor layer 14n. However, the invention is not limited to this configuration. For example, solar cell substrate 10 may be formed of semiconductor substrate 15 having p-type region 10ap in which a p-type dopant being diffused and n-type region 10an in which an n-type dopant being diffused.

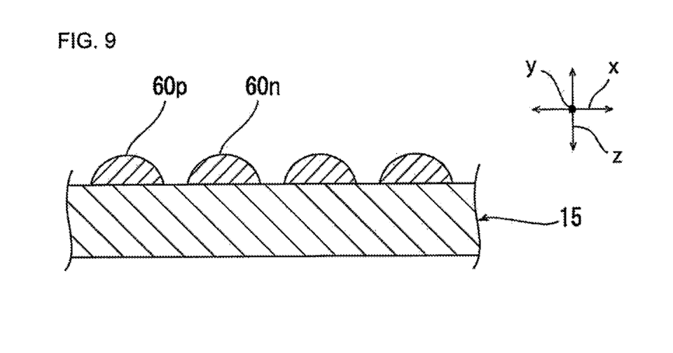

In the second embodiment, as shown in FIG. 9, a diffusion agent 60p containing a p-type dopant and a diffusion agent 60n containing an n-type dopant are applied to surface 15a of semiconductor substrate 15, which is cut out from semiconductor ingot 20 as in the case of the first embodiment. Thus, p-type region 10ap and n-type region 10an can be formed through thermal diffusion of the p-type and n-type dopants.

Since the second embodiment can similarly suppress wetting and spreading of diffusion agents 60p, 60n, as in the case of the first embodiment, p-type region 10ap and n-type region 10an, as well as electrodes 17p, 17n can be formed with high accuracy. Accordingly, conversion efficiency of solar cell 1 can be improved.

What is claimed is:

1. A solar cell comprising:
a solar cell substrate including a semiconductor substrate and having a surface of a p-type region and a surface of an n-type region on a first principal surface's side of the solar cell substrate;
a p-side electrode formed on the surface of the p-type region; and
an n-side electrode formed on the surface of the n-type region, wherein
the semiconductor substrate includes linear grooves extending in a first direction on a surface on a first principal surface side, and
each of the p-side electrode and the n-side electrode includes one or more linear portions extending in the first direction.

2. The solar cell according to claim 1, wherein the one or more linear portions of the p-side electrode and the one or more linear portions of the n-side electrode are arranged next to each other in a second direction orthogonal to the first direction.

3. The solar cell according to claim 1, wherein the linear grooves are saw marks.

4. The solar cell according to claim 1, wherein each of the surface of the p-type region and the surface of the n-type region includes one or more linear portions extending in the first direction, corresponding to the one or more linear portions of each of the p-side electrode and the n-side electrode.

5. The solar cell according to claim 1, wherein each of the one or more linear portions of the p-side electrode and the one or more linear portions of the n-side electrode includes a conductive paste layer.

6. The solar cell according to claim 1, wherein the solar cell substrate includes, on the first principal surface, linear grooves corresponding to the linear grooves of the semiconductor substrate.

7. The solar cell according to claim 1, wherein the solar cell substrate includes a p-type semiconductor layer formed on the surface of the semiconductor substrate and forming the p-type region, and an n-type semiconductor layer formed on the surface of the semiconductor substrate and forming the n-type region.

8. The solar cell according to claim 1, wherein the solar cell substrate includes a p-type dopant diffusion region forming the p-type region in the semiconductor substrate, and an n-type dopant diffusion region forming the n-type region in the semiconductor substrate.

9. A method of manufacturing a solar cell, comprising the:
preparing a semiconductor substrate including a principal surface with linear grooves extending in a first direction;
forming, by use of the semiconductor substrate, a solar cell substrate on which a surface of a p-type region and a surface of an n-type region are on a principal surface side; and
forming a p-side electrode on the surface of the p-type region and forming an n-side electrode on the surface of the n-type region such that each of the p-side electrode and the n-side electrode includes one or more linear portions extending in the first direction.

10. The method of manufacturing the solar cell according to claim 9, wherein the one or more linear portions are formed of a conductive paste.

11. The method of manufacturing the solar cell according to claim 9, wherein the step of forming the solar cell substrate comprises forming a first semiconductor layer of one conductivity type on a first region of the principal surface of the semiconductor substrate, and forming a second semiconductor layer of another conductivity type on a second region, other than the first region, of the principal surface of the semiconductor substrate, the first semiconductor layer forming one of the p-type region and the n-type region, the second semiconductor layer forming the other of the p-type region and the n-type region.

12. The method of manufacturing the solar cell according to claim 11, wherein the step of forming the first semiconductor layer comprises forming a semiconductor layer of the one conductivity type on a surface of the semiconductor substrate, and applying an etchant to a portion other than a portion above the first region of the semiconductor substrate, thereby etching the layer.

13. The method of manufacturing the solar cell according to claim 11, wherein the step of forming the first semiconductor layer comprises forming a semiconductor layer of the one conductivity type on a surface of the semiconductor substrate, forming a mask layer on the first region on a surface of the semiconductor layer, and then etching a region exposed from the mask layer.

14. The method of manufacturing the solar cell according to claim 9, wherein
the p-type region is formed by applying a first diffusion agent containing a p-type dopant to a first region of the principal surface of the semiconductor substrate and diffusing the p-type dopant in the first region, and
the n-type region is formed by applying a second diffusion agent containing an n-type dopant to a second region, other than the first region, of the principal surface of the semiconductor substrate and diffusing the n-type dopant in the second region.

15. The method of manufacturing the solar cell according to claim 9, wherein the semiconductor substrate is formed by cutting a semiconductor ingot by using a wire saw.

16. The method of manufacturing the solar cell according to claim 15, wherein the wire saw is a fixed abrasive wire saw.

17. The solar cell according to claim 2, wherein the one or more linear portions of the p-side electrode comprises a plurality of linear portions of the p-side electrode and the one or more linear portions of the n-side electrode comprises a plurality of linear portions of the n-side electrode, and
the linear portions of the p-side electrode and the linear portions of the n-side electrode are alternatively arranged each other.
